(19) United States
(12) Patent Application Publication
(10) Pub. No.: US 2026/0112862 A1
(43) Pub. Date: Apr. 23, 2026

(54) Reflective optical amplifier array with shared drive

(71) Applicant: Lyte AI, Inc., Mountain View, CA (US)

(72) Inventor: Andrew J.H. Sutton, Amaroo (AU)

(21) Appl. No.: 18/998,570

(22) PCT Filed: Jul. 9, 2024
(86) PCT No.: PCT/US2024/037118

§ 371 Date: Jan. 27, 2025

Related U.S. Application Data
(60) Provisional application No. 63/512,629, filed on Jul. 9, 2023.
(60) Provisional application No. 63/589,640, filed on Oct. 12, 2023.

(51) Int. Cl. H01S 5/40; G02B 27/28; H01S 5/00

(52) U.S. Cl. CPC H01S 5/4025; G02B 27/283; G02B 27/286; H01S 5/0064

(57) ABSTRACT

An integrated optical device (20, 70, 80, 90, 100) includes an amplifier chip (22), which includes a plurality of multi-pass semiconductor optical gain media (60, 92) having respective reflective ends (61) and respective transmissive ends (63) and multiple first optical couplers (58) optically coupled respectively to the transmissive ends of the optical gain media. A photonics chip (24) includes multiple second optical couplers (50), which are aligned respectively with the first optical couplers on the amplifier chip, and optical circuitry (51), which directs a coherent seed beam through the second optical couplers for input via the first optical couplers to the multi-pass semiconductor optical gain media and to receive amplified beams from the multi-pass semiconductor optical gain media via the first and second optical couplers.

### CROSS-REFERENCE TO RELATED APPLICATION

This application claims the benefit of U.S. Provisional Patent Application 63/512,629, filed Jul. 9, 2023, and U.S. Provisional Patent Application 63/589,640, filed Oct. 12, 2023. Both of these related applications are incorporated herein by reference.

### FIELD

The present invention relates generally to integrated optoelectronic devices, and particularly to integrated sources of coherent optical radiation.

### BACKGROUND

Silicon photonic integrated circuits (SPICs) are commonly used in optical transmitter and transceiver arrays. Some active optoelectronic components, however, such as semiconductor lasers and semiconductor optical amplifiers (SOAs), comprise III-V semiconductor compounds (such as GaAs or InP). These components are typically fabricated on a III-V wafer. After fabrication, the III-V wafer is diced to produce singulated III-V chiplets, which are then aligned and mounted in the appropriate locations on the SPIC.

The terms “optical radiation” and “light” are used synonymously in the present description and in the claims to refer to electromagnetic radiation in any or all of the visible, infrared, and ultraviolet spectral ranges.

### SUMMARY

Embodiments of the present invention that are described hereinbelow provide improved integrated sources of coherent optical radiation.

There is therefore provided, in accordance with an embodiment of the invention, an integrated optical device, which includes an amplifier chip, including a plurality of multi-pass semiconductor optical gain media having respective reflective ends and respective transmissive ends and multiple first optical couplers optically coupled respectively to the transmissive ends of the optical gain media. A photonics chip includes multiple second optical couplers, which are aligned respectively with the first optical couplers on the amplifier chip, and optical circuitry configured to direct a coherent seed beam through the second optical couplers for input via the first optical couplers to the multi-pass semiconductor optical gain media and to receive amplified beams from the multi-pass semiconductor optical gain media via the first and second optical couplers.

In a disclosed embodiment, the amplifier chip includes a substrate including a III-V semiconductor compound, on which the multi-pass semiconductor optical gain media are disposed, and the photonics chip includes a silicon photonic integrated circuit (SPIC).

In some embodiments, the device includes a laser configured to generate the coherent seed beam for input to the optical circuitry. In one embodiment, the laser is disposed on the photonics chip. Additionally or alternatively, the device includes an interferometer disposed on the photonics chip, which is configured to sense a frequency variation in the seed beam, and control circuitry configured to drive the laser responsively to the sensed frequency variation.

In a disclosed embodiment, the multi-pass semiconductor optical gain media include reflective semiconductor optical amplifiers. Alternatively, the multi-pass semiconductor optical gain media include semiconductor lasers.

In a disclosed embodiment, the device includes an array of microlenses disposed between the first and second optical couplers.

Additionally or alternatively, the device includes an optical isolator configured to pass the seed beam from the second optical couplers to the first optical couplers and to pass the amplified beams from the first optical couplers to the second optical couplers while attenuating back-reflections from the photonics chip to the amplifier chip. In some embodiments, the optical isolator includes a waveplate and a polarization rotator, and wherein the seed beam is directed through the second optical couplers with a first linear polarization, which is rotated by the polarization rotator to a second linear polarization, orthogonal to the first linear polarization, for input through the first optical couplers to the multi-pass semiconductor optical gain media. For example, the waveplate includes a half-wave plate, and the polarization rotator includes a Faraday rotator.

In some embodiments, the optical circuitry includes an input waveguide configured to convey the coherent seed beam across the photonics chip, multiple taps coupled to extract respective fractions of the seed beam from the input waveguide, multiple output waveguides, and multiple splitters, coupled to direct the respective fractions of the seed beam from the respective taps to the second optical couplers for input to the multi-pass semiconductor optical gain media and to convey the amplified beams output by the multi-pass semiconductor optical gain media from the second optical couplers to the output waveguides.

In some embodiments, the device includes an optical isolator including a half-wave plate and a Faraday rotator disposed between the first and second optical couplers. In a disclosed embodiment, the coherent seed beam propagates through the input waveguide with a first linear polarization, while the amplified beams received through the second optical couplers have a second linear polarization, orthogonal to the first linear polarization, and wherein the splitters include polarization splitters.

Alternatively, both the coherent seed beam propagating through the input waveguide and the amplified beams received through the second optical couplers have a first linear polarization, and the splitters include polarization splitters and rotators, which rotate the seed beam from the first linear polarization to a second linear polarization, orthogonal to the first linear polarization. Further alternatively, the splitters include directional couplers, having a first coupling ratio for conveying the seed beam from the respective taps to the second optical couplers and a second coupling ratio, which is at least twice the first coupling ratio, for conveying the amplified beams output by the multi-pass semiconductor optical gain media from the second optical couplers to the output waveguides.

There is also provided, in accordance with an embodiment of the invention, a method for optical beam generation, including providing an amplifier chip, which includes a plurality of multi-pass semiconductor optical gain media having respective reflective ends and respective transmissive ends and multiple first optical couplers optically coupled respectively to the transmissive ends of the optical gain media. Multiple second optical couplers on a photonics chip are aligned with the first optical couplers on the amplifier chip so as to direct a coherent seed beam from the photonics chip through the second optical couplers for input via the first optical couplers to the multi-pass semiconductor optical gain media and to receive amplified beams in the photonics chip from the multi-pass semiconductor optical gain media via the first and second optical couplers.

The present invention will be more fully understood from the following detailed description of the embodiments thereof, taken together with the drawings in which:

### BRIEF DESCRIPTION OF THE DRAWINGS

FIG. 1 is a schematic top view of a multichannel optical transmitter, in accordance with embodiments of the invention;

FIG. 2 is a schematic detail view of optical coupling components used in the transmitter of FIG. 1, in accordance with an embodiment of the invention;

FIGS. 3, 4, 5 and 6 are schematic top views of multichannel optical transmitters, in accordance with further embodiments of the invention; and

FIG. 7 is a schematic detail view of optical coupling components used in the transmitter of FIG. 6, in accordance with an embodiment of the invention.

### DETAILED DESCRIPTION

### OVERVIEW

Some semiconductor optical transmitter and transceiver devices include multiple transmission channels, each with its own optical gain media, such as an SOA or laser. When each of the optical gain media is mounted on its own III-V chiplet, as described above in the Background section, the difficulty and cost of aligning all the optical gain media with the appropriate waveguides on the SPIC can be substantial.

PCT Patent Application PCT/US2024/032680, filed Jun. 6, 2024, whose disclosure is incorporated herein by reference, describes a solution to this problem in which multiple SOAs are fabricated on a single III-V chip, together with respective input and output waveguides. A splitter divides an input laser beam among the input waveguides. The splitter and waveguides on the III-V chip are fabricated together with the SOAs using III-V materials, and thus the SOAs are inherently aligned with the waveguides. The multiple outputs of the III-V chip, each provided by a respective SOA, can then be aligned with the corresponding channels on a SPIC in a single inter-chip alignment operation.

Embodiments of the present invention that are described herein take this concept a step further using arrays of multi-pass semiconductor optical gain media, such as reflective semiconductor optical amplifiers (RSOAs) or semiconductor lasers. The term “multi-pass semiconductor optical gain media,” as used in the present description and in the claims, refers to a component that includes an optical gain medium having one end that is reflective and an opposite send that is (at least partially) transmissive. An integrated reflector at the reflective end causes coherent light that has passed through and been amplified by the optical gain medium to pass through the gain medium at least one more time and be amplified further. The integrated reflector may comprise, for example, a reflectively coated end-facet of the gain medium, a distributed Bragg reflector (DBR) or a distributed feedback reflector (DFB). An RSOA typically includes a single reflector at the reflective end, which causes seed light entering the transmissive end of the RSOA to make two passes through the gain medium before exiting from the end through which it entered. A semiconductor laser typically includes reflectors at both ends, such as a high reflector at the reflective end and a partial reflector at the transmissive end, through which a seed beam may enter and through which the amplified laser beam exits.

Thus, the disclosed embodiments provide integrated optical devices comprising an amplifier chip and a photonics chip. The amplifier chip comprises a plurality of multi-pass semiconductor optical gain media, having respective reflective ends and respective transmissive ends, and multiple optical couplers, which are coupled respectively to the transmissive ends of the optical gain media. As noted earlier, the amplifier chip typically comprises a III-V semiconductor compound but may alternatively comprise other suitable substrate materials. The multi-pass semiconductor optical gain media may comprise either RSOAs or semiconductor lasers. In the disclosed embodiments, the optical couplers comprise edge couplers, but alternatively other sorts of couplers may be used, such as grating couplers.

The photonics chip also comprises multiple optical couplers, which are aligned respectively with the optical couplers on the amplifier chip, thus defining pairs of optical couplers. As the spatial relations between the optical couplers within each chip are defined precisely by photolithography, only a single alignment operation is required to align the two chips. An array of microlenses may be aligned between the pairs of optical couplers to improve coupling efficiency. Optical circuitry on the photonics chip directs a coherent seed beam through the pairs of optical couplers to the multi-pass semiconductor optical gain media on the amplifier chip and receives the amplified beams from the multi-pass semiconductor optical gain media via the same pairs of optical couplers. As explained below, the optical components provide isolation or separation between seed and amplified light fields using directional or polarization-selective circuit elements. In the disclosed embodiments, the photonics chip comprises a SPIC, but alternatively, other sorts of substrates and integrated optical technologies may be used in producing the photonics chip.

In some embodiments, an optical isolator, positioned between the pairs of optical couplers, permits the seed beam to pass from the photonics chip to the amplifier chip and permits the amplified beams to pass from the amplifier chip to the photonics chip, while preventing back-reflections of the amplified beams from the photonics chip to the amplifier chip. For this purpose, for example, the seed beam output from the optical couplers on the photonics chip and the amplified beams output from the optical couplers on the amplifier chip may have orthogonal linear polarizations, and the optical isolator may comprise a waveplate and a polarization rotator, such as a half-wave plate and a Faraday rotator.

In the disclosed embodiments, the optical circuitry on the photonics chip receives the coherent seed beam from a seed laser (which may be mounted on the photonics chip or in a separate component) and distributes the seed beam among the optical couplers for input to the amplifier chip. In some embodiments, the optical circuitry comprises an input waveguide, which conveys the coherent seed beam across the photonics chip, and multiple taps coupled to extract respective fractions of the seed beam from the input waveguide. Corresponding splitters direct the respective fractions of the seed beam from the taps to the optical couplers for input to the multi-pass semiconductor optical gain media, while conveying the amplified beams output by the multi-pass semiconductor optical gain media from the optical couplers to output waveguides on the photonics chip.

Additional components of the optical circuitry may be used, for example, to condition and transmit the amplified beams as channels of a multi-channel transmitter or transceiver system, for example as described in described in PCT International Publication WO 2023/023106, whose disclosure is incorporated herein by reference. These aspects of the device, however, are beyond the scope of the present description.

### DEVICE DESIGNS

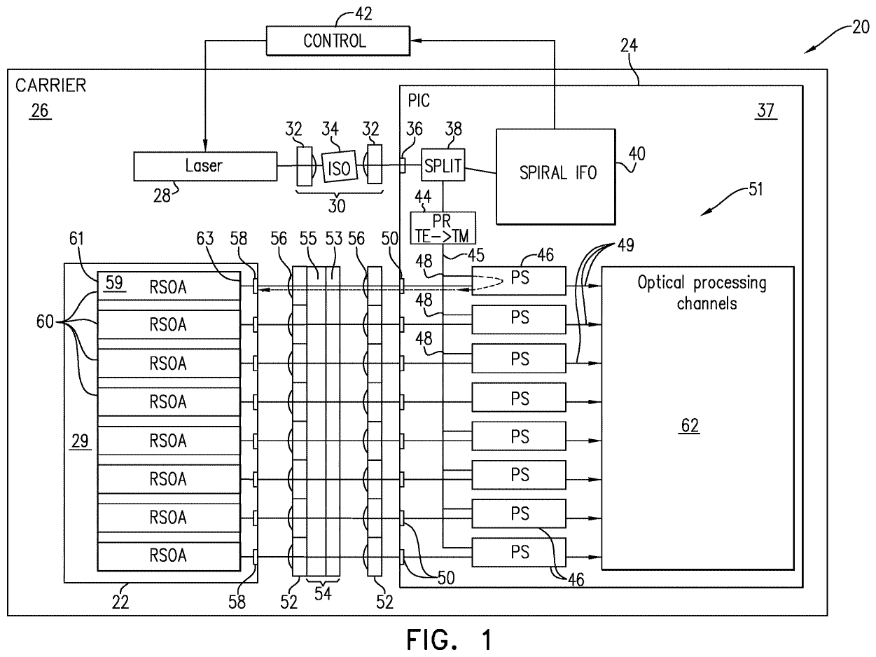

FIG. 1 is a schematic top view of a multichannel optical transmitter 20, in accordance with an embodiment of the invention. Transmitter 20 is an integrated optical device comprising an amplifier chip 22 and a photonics chip 24, which are mutually aligned on a carrier substrate 26, such as a silicon wafer substrate.

Amplifier chip 22 comprises a semiconductor substrate 29, for example a III-V substrate, such as GaAs or InP. Amplifier chip 22 in this embodiment comprises multiple RSOAs 60, which are fabricated on substrate 29 by processes of thin film deposition and photolithography, as are known in the art. Each RSOA 60 comprises an optical gain medium 59 with a reflective end 61 and a transmissive end 63. Optical couplers 58, such as edge couplers, on substrate 29 are optically coupled respectively to transmissive ends 63, for example by optical waveguides. Electrical bias applied to RSOAs 60 causes the RSOAs to amplify input seed beams received through optical couplers 58 and to output amplified beams through the respective optical couplers.

A laser 28 on carrier substrate 26, such as a distributed feedback (DFB) laser, generates the seed beam of coherent radiation for input to photonics chip 24. An optical relay 30 is aligned on substrate 26 to receive the seed beam from laser 28 and input the seed beam to an input coupler 36 on photonics chip 24. In the pictured example, optical relay 30 comprises one or more microlenses 32 and an optical isolator 34, to prevent back-reflections from photonics chip 34 to laser 28.

Photonics chip 24 comprises a silicon-based substrate 37, such as a silicon-on-insulator (SOI) substrate. Multiple optical couplers 50 on substrate 37 are aligned respectively with optical couplers 58 on amplifier chip 22. Optical couplers 50 in this example similarly comprise edge couplers, like couplers 58. Alternatively, other sorts of optical couplers may be used, such as grating couplers. To improve coupling efficiency, one or more arrays 52 of microlenses 56 are aligned between optical couplers 50 on substrate 37 and optical couplers 58 on substrate 29.

In addition, an optical isolator 54 is coupled in series with microlens arrays 52 to pass the seed beam from optical couplers 50 to optical couplers 58 and to pass the amplified beams from optical couplers 58 to optical couplers 50 while attenuating back-reflections of the amplified beam from photonics chip 24 to amplifier chip 22. In the present example, optical isolator 54 comprises a waveplate 53 and a Faraday rotator 55. Waveplate 53 typically comprises a half-wave plate. Optionally, optical isolator 54 may comprise a polarizer (not shown) aligned to transmit only the amplified polarization for the RSOA. In general, however, a polarizer is not needed since the output of RSOAs 60 (as well as of laser 28) is typically polarized in the TE-mode direction. Back-reflections will be rotated by Faraday rotator 55 and waveplate 53 to the TM-mode direction and will therefore have little effect on RSOAs 60 even in the absence of a polarizer. Alternatively, other sorts of optical isolators may be used, as are known in the art.

Optionally, to control and stabilize laser 28, a splitter 38 on photonics chip 24 feeds a part of the seed beam to an interferometer 40 on the photonics chip, such as a Mach-Zehnder interferometer with a spiral delay line. The splitting ratio of splitter 38 is chosen based on considerations such as the power output by laser 28 and the required power level of the seed beam. Interferometer 40 outputs a signal that is indicative of frequency variations in the seed beam. Control circuitry 42 uses the signal output by the interferometer as a feedback signal for driving laser 28. This arrangement is advantageous in that all the output beams are locked and stabilized by control of the single seed laser. For example, in some applications, control circuitry 42 applies frequency stabilization or modulation, such as a frequency chirp, to the laser and uses the feedback signal from interferometer 40 in linearizing the chirp. For the sake of simplicity, control circuitry 42 is omitted from the figures that follow.

Optical circuitry 51 on photonics chip 24 distributes the coherent seed beam (which was received via input coupler 36) among optical couplers 50 for input (via optical couplers 58) to RSOAs 60 and receives the amplified beams from RSOAs 60 via optical couplers 50. Various possible implementations of optical circuitry 51 are shown in the figures that follow. In the disclosed embodiments, an input waveguide 45 conveys the coherent seed beam across photonics chip 24, and multiple taps 48 extract respective fractions of the seed beam from the input waveguide for output to RSOAs 60. Splitters 46 direct the respective fractions of the seed beam from respective taps 48 to optical couplers 50 for output to amplifier chip 22 while conveying the amplified beams received through optical couplers 50 to output waveguides 49. In the present embodiment, a polarization rotator (PR) 44 rotates the polarization of the seed beam from TE to TM, so that the seed beam propagates through input waveguide 45 with TM polarization, while the amplified beams received through optical couplers 50 are TE-polarized. In this case, splitters 46 comprise polarization splitters.

Output waveguides 49 convey the amplified beams to optical processing circuitry 62. For example, optical processing circuitry 62 may comprise an optical distribution network, which distributes the amplified sub-beams among an array of transmitter or transceiver cells, such as the sorts of cells that are described in the above-mentioned PCT International Publication WO 2023/023106.

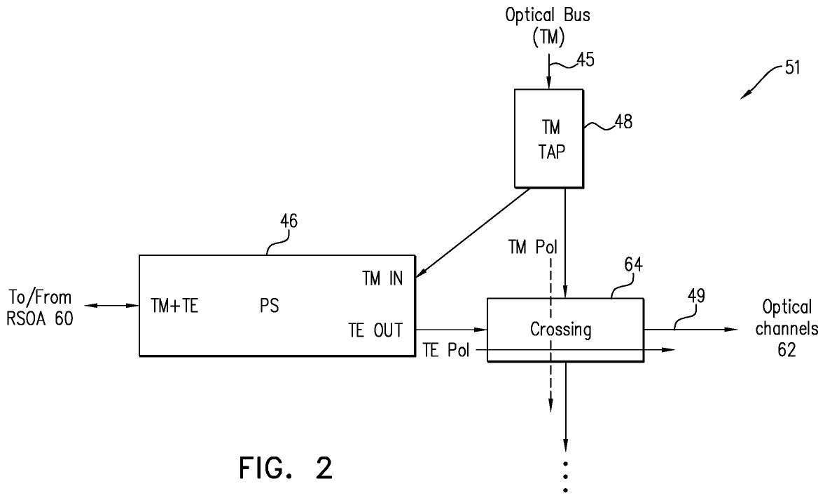

FIG. 2 is a schematic detail view of optical coupling components used in transmitter 20, in accordance with an embodiment of the invention. This figure shows a single channel of optical circuitry 51.

As explained above, the seed beam in this embodiment propagates through input waveguide 45 in the TM mode. Tap 48 splits off a fraction of the seed beam for input to polarization splitter 46. The tap ratios are selected so that each channel receives a roughly equal fraction of the power in the seed beam. (In other words, in the example shown in FIG. 1, the tap ratio increases in the successive taps with the distance of the tap from polarization rotator 44.) Polarization splitter 46 passes the TM seed beam to RSOA 60 via polarization rotator 54, which rotates the beam to TE polarization. Because of the directional properties of the polarization rotator, however, the amplified TE beam returned by RSOA 60 is not rotated on the way back and is thus output through the TE output port of polarization splitter 46.

The waveguide carrying the TE amplified beam to output waveguide 49 crosses input waveguide 45, carrying the TM seed beam, at a crossing 64. Because the beams have opposite polarizations, there is negligible coupling between the beams in crossing 64.

### ALTERNATIVE EMBODIMENTS

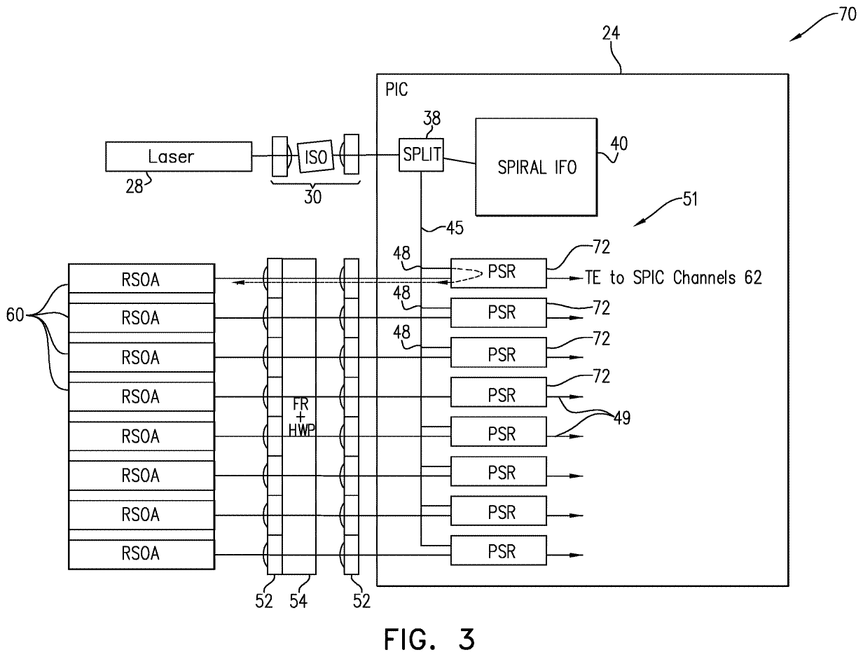

FIG. 3 is a schematic top view of a multichannel optical transmitter 70, in accordance with an alternative embodiment of the invention. The components of transmitter 70 are similar to those of transmitter 20 (FIG. 1), and the same reference numbers are used to indicate similar components. For the sake of brevity and simplicity, some of the similar components are omitted from FIG. 3, and only the elements of this embodiment that differ from those of the embodiment of FIG. 1 will be described below. The embodiments shown in the figures that follow will be described in a similar fashion.

In transmitter 70, the seed beam from laser 28 is transmitted through input waveguide 45 in the original TE polarization, without rotation to the TM mode as in the preceding embodiment. Taps 48 convey the respective fractions of the seed beam to polarization splitter/rotators (PSRs) 72, which rotate the seed beam to TM polarization and convey the seed beam in TM polarization through optical isolator 54 to RSOAs 60. The amplified beams from RSOAs 60, with TE polarization, pass through PSRs 72 without change in polarization to output waveguides 49.

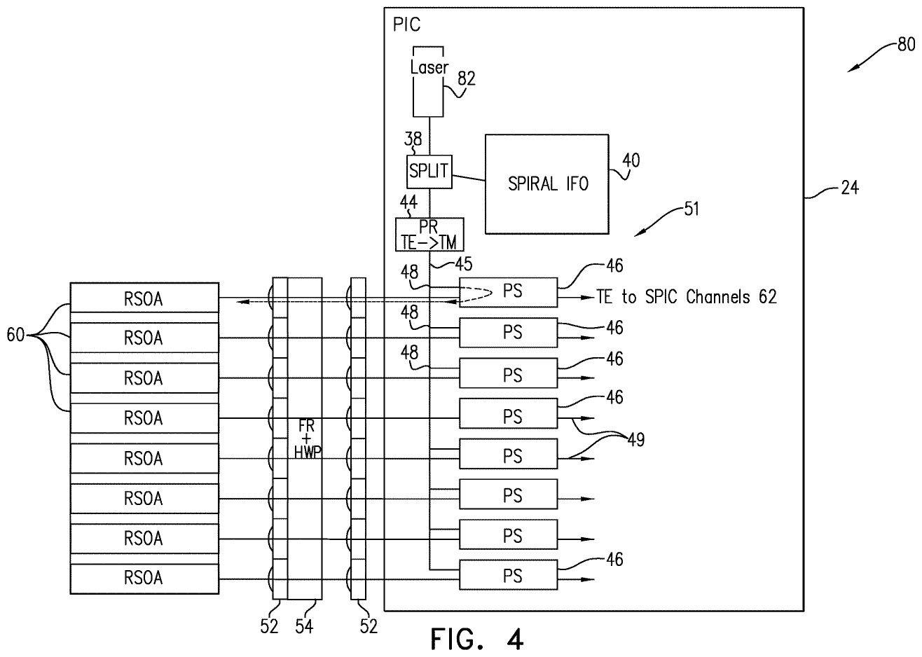

FIG. 4 is a schematic top view of a multichannel optical transmitter 80, in accordance with yet another embodiment of the invention. Transmitter 80 is similar in structure and operation to transmitter 20 (FIG. 1), except that the seed beam in transmitter 80 is generated by a laser 82 on photonics chip 24. This embodiment is advantageous in alleviating the need to align the laser chip with the photonics chip as in the preceding embodiments.

In a further alternative embodiment (not shown in the figures), the separate laser chip in transmitter 70 (FIG. 3) is replaced by an on-chip laser as in FIG. 4.

### INJECTION-LOCKED LASER ARRAYS

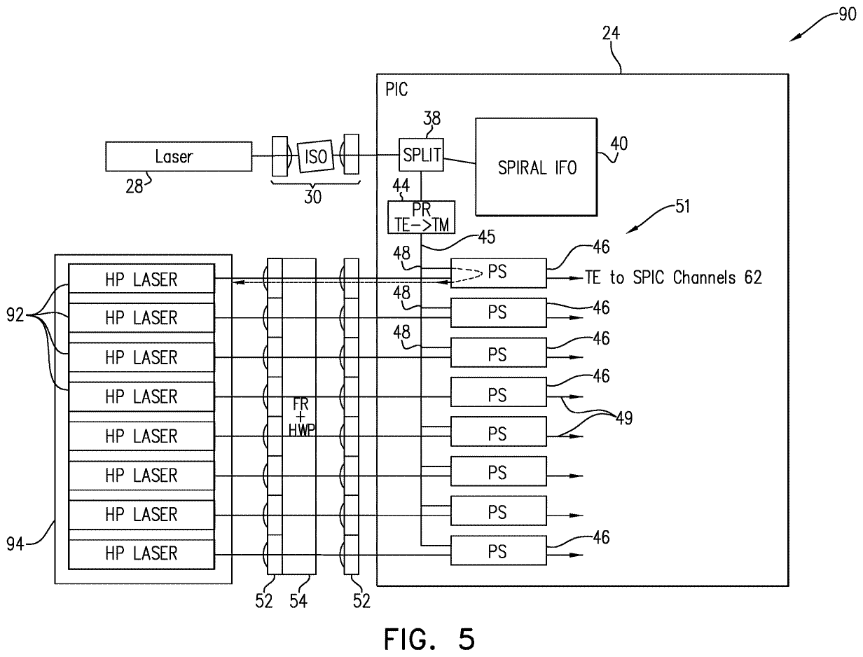

FIG. 5 is a schematic top view of a multichannel optical transmitter 90, in accordance with a further embodiment of the invention. This embodiment is again similar to transmitter 20 (FIG. 1), except that in the present embodiment, transmitter 90 comprises an array of high-power (HP) lasers 92 on an amplifier chip 94, instead of the RSOAs in the preceding embodiments. Lasers 92 may comprise multi-frequency Fabry-Perot lasers or high-power DFB lasers, for example. Such lasers typically have wide spectral bandwidth and low coherence times, making them unsuitable for applications such as coherent LIDAR and optical communications. In transmitter 90, however, lasers 92 are injection-locked by the stabilized, narrowband seed beam and thus operate with narrower bandwidth and enhanced coherence that are required for LIDAR and other high-fidelity applications.

In an alternative embodiment (not shown in the figures), polarization rotator 44 is eliminated from transmitter 90, and polarization splitters 46 are replaced by polarization splitter/rotators, as in the embodiment of FIG. 3. In other embodiments, seed laser 28 is replaced by an on-chip laser, such as laser 82 (FIG. 4).

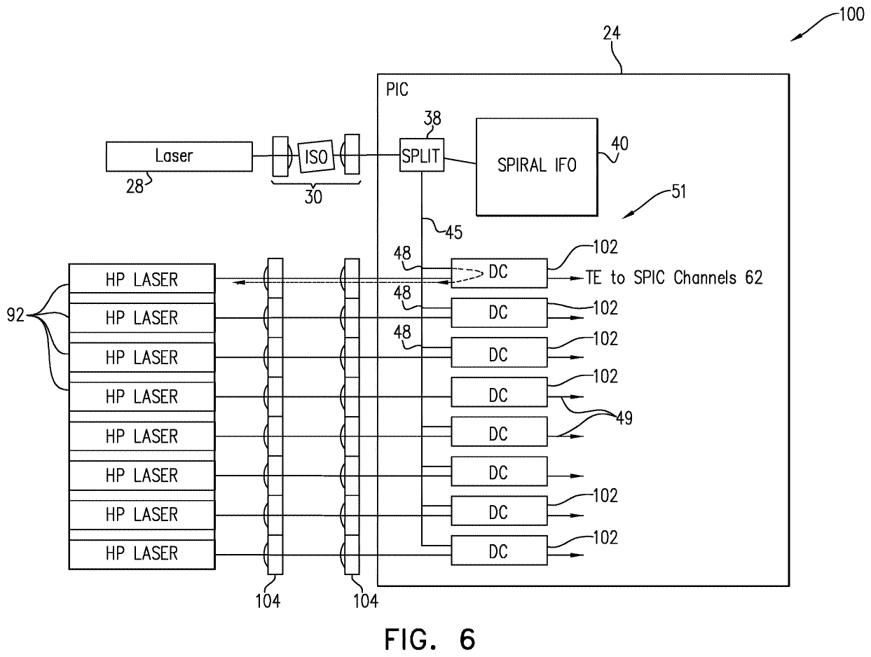

FIG. 6 is a schematic top view of a multichannel optical transmitter 100, in accordance with another embodiment of the invention. In this embodiment, TE polarization is used throughout photonics chip 24, and the polarization-based optical isolator between lasers 92 on the amplifier chip and the couplers on the photonics chip is eliminated. One or more microlens arrays 104 are used to improve the coupling efficiency between the amplifier chip and the photonics chip, without isolation. In the absence of polarization components, directional couplers 102 on photonics chip 24 are used to direct the seed beam from taps 48 toward lasers 92 while directing the output beams from lasers 92 into output waveguides 49.

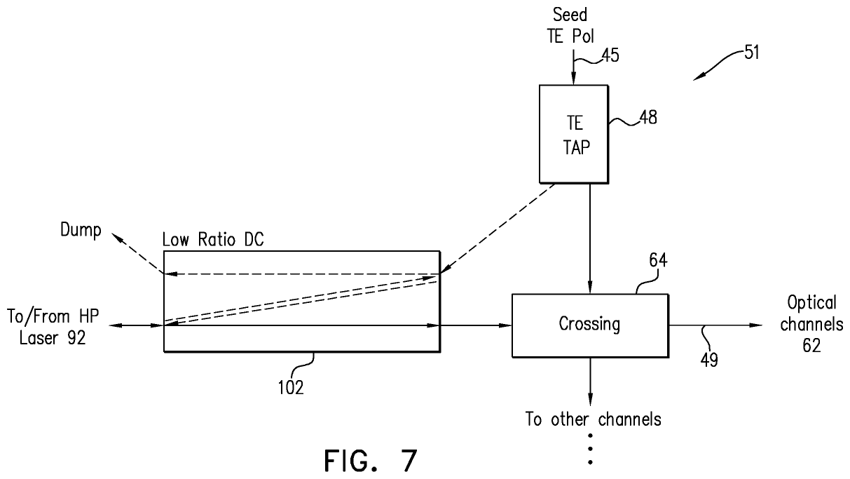

FIG. 7 is a schematic detail of optical coupling components used in transmitter 100, in accordance with an embodiment of the invention. This figure shows a single channel of optical circuitry 51 in the multi-channel transmitter.

In this embodiment, the seed beam propagates through input waveguide 45 in the TE mode. Tap 48 splits off a fraction of the seed beam for input to directional coupler 102, which passes a small fraction of the energy in the seed beam to laser 92 and discards most of the energy in the seed beam in a suitable beam dump. At the same time, directional coupler 102 passes most of the energy output by laser 92 to output waveguide 49. The fraction of the energy that is input to the directional coupler in a given direction relative to the energy output in the same direction is referred to as the coupling ratio. For high output efficiency, directional coupler 102 has a substantially lower coupling ratio for conveying the seed beam from tap 48 to laser 92 than for conveying the output beam from the laser to output waveguide 49. For example, the coupling ratio for conveying the output beam to the output waveguide is typically at least twice the coupling ratio for conveying the seed beam to the laser, and may be as much as ten times greater.

The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An integrated optical device, comprising:
an amplifier chip, comprising:
a plurality of multi-pass semiconductor optical gain media having respective reflective ends and respective transmissive ends; and
multiple first optical couplers optically coupled respectively to the transmissive ends of the optical gain media; and
a photonics chip, comprising:
multiple second optical couplers, which are aligned respectively with the first optical couplers on the amplifier chip; and
optical circuitry configured to direct a coherent seed beam through the second optical couplers for input via the first optical couplers to the multi-pass semiconductor optical gain media and to receive amplified beams from the multi-pass semiconductor optical gain media via the first and second optical couplers.

2. The device according to claim 1, wherein the amplifier chip comprises a substrate comprising a III-V semiconductor compound, on which the multi-pass semiconductor optical gain media are disposed.

3. The device according to claim 2, wherein the photonics chip comprises a silicon photonic integrated circuit (SPIC).

4. The device according to claim 1, and comprising a laser configured to generate the coherent seed beam for input to the optical circuitry.

5. The device according to claim 4, wherein the laser is disposed on the photonics chip.

6. The device according to claim 4, and comprising:
an interferometer disposed on the photonics chip, which is configured to sense a frequency variation in the seed beam; and
control circuitry configured to drive the laser responsively to the sensed frequency variation.

7. The device according to claim 1, wherein the multi-pass semiconductor optical gain media comprise reflective semiconductor optical amplifiers.

8. The device according to claim 1, wherein the multi-pass semiconductor optical gain media comprise semiconductor lasers.

9. The device according to claim 1, and comprising an array of microlenses disposed between the first and second optical couplers.

10. The device according to claim 1, and comprising an optical isolator configured to pass the seed beam from the second optical couplers to the first optical couplers and to pass the amplified beams from the first optical couplers to the second optical couplers while attenuating back-reflections from the photonics chip to the amplifier chip.

11. The device according to claim 10, wherein the optical isolator comprises a waveplate and a polarization rotator, and wherein the seed beam is directed through the second optical couplers with a first linear polarization, which is rotated by the polarization rotator to a second linear polarization, orthogonal to the first linear polarization, for input through the first optical couplers to the multi-pass semiconductor optical gain media.

12. The device according to claim 11, wherein the waveplate comprises a half-wave plate, and the polarization rotator comprises a Faraday rotator.

13. The device according to any of claim 1, wherein the optical circuitry comprises:
an input waveguide configured to convey the coherent seed beam across the photonics chip;
multiple taps coupled to extract respective fractions of the seed beam from the input waveguide;
multiple output waveguides; and
multiple splitters, coupled to direct the respective fractions of the seed beam from the respective taps to the second optical couplers for input to the multi-pass semiconductor optical gain media and to convey the amplified beams output by the multi-pass semiconductor optical gain media from the second optical couplers to the output waveguides.

14. The device according to claim 13, and comprising an optical isolator comprising a half-wave plate a Faraday rotator disposed between the first and second optical couplers.

15. The device according to claim 14, wherein the coherent seed beam propagates through the input waveguide with a first linear polarization, while the amplified beams received through the second optical couplers have a second linear polarization, orthogonal to the first linear polarization, and wherein the splitters comprise polarization splitters.

16. The device according to claim 14, wherein both the coherent seed beam propagating through the input waveguide and the amplified beams received through the second optical couplers have a first linear polarization, and wherein the splitters comprise polarization splitters and rotators, which rotate the seed beam from the first linear polarization to a second linear polarization, orthogonal to the first linear polarization.

17. The device according to claim 13, wherein the splitters comprise directional couplers, having a first coupling ratio for conveying the seed beam from the respective taps to the second optical couplers and a second coupling ratio, which is at least twice the first coupling ratio, for conveying the amplified beams output by the multi-pass semiconductor optical gain media from the second optical couplers to the output waveguides.

18. A method for optical beam generation, comprising:
providing an amplifier chip, comprising:
a plurality of multi-pass semiconductor optical gain media having respective reflective ends and respective transmissive ends; and
multiple first optical couplers optically coupled respectively to the transmissive ends of the optical gain media; and
aligning multiple second optical couplers on a photonics chip with the first optical couplers on the amplifier chip so as to direct a coherent seed beam from the photonics chip through the second optical couplers for input via the first optical couplers to the multi-pass semiconductor optical gain media and to receive amplified beams in the photonics chip from the multi-pass semiconductor optical gain media via the first and second optical couplers.

19. The method according to claim 18, wherein the amplifier chip comprises a substrate comprising a III-V semiconductor compound, on which the multi-pass semiconductor optical gain media are disposed.

20. The method according to claim 19, wherein the photonics chip comprises a silicon photonic integrated circuit (SPIC).

21. The method according to claim 18, and comprising providing a laser to generate the coherent seed beam for input to the optical circuitry.

22. The method according to claim 21, wherein providing the laser comprises mounting the laser on the photonics chip.

23. The method according to claim 21, and comprising:
sensing a frequency variation in the seed beam using an interferometer on the photonics chip; and
driving the laser responsively to the sensed frequency variation.

24. The method according to claim 18, wherein the multi-pass semiconductor optical gain media comprise reflective semiconductor optical amplifiers.

25. The method according to claim 18, wherein the multi-pass semiconductor optical gain media comprise semiconductor lasers.

26. The method according to claim 18, wherein aligning the multiple second optical couplers comprises positioning an array of microlenses between the first and second optical couplers.

27. The method according to claim 18, wherein aligning multiple second optical couplers comprises positioning an optical isolator to pass the seed beam from the second optical couplers to the first optical couplers and to pass the amplified beams from the first optical couplers to the second optical couplers while attenuating back-reflections from the photonics chip to the amplifier chip.

28. The method according to claim 27, wherein the optical isolator comprises a waveplate and a polarization rotator, and wherein aligning the multiple second optical couplers comprises directing the seed beam through the second optical couplers with a first linear polarization, which is rotated by the polarization rotator to a second linear polarization, orthogonal to the first linear polarization, for input through the first optical couplers to the multi-pass semiconductor optical gain media.

29. The method according to claim 28, wherein the waveplate comprises a half-wave plate, and the polarization rotator comprises a Faraday rotator.

30. The method according to claim 18, wherein the photonics chip comprises:
an input waveguide to convey the coherent seed beam across the photonics chip;
multiple taps to extract respective fractions of the seed beam from the input waveguide;
multiple output waveguides; and
multiple splitters, to direct the respective fractions of the seed beam from the respective taps to the second optical couplers for input to the multi-pass semiconductor optical gain media and to convey the amplified beams output by the multi-pass semiconductor optical gain media from the second optical couplers to the output waveguides.

31. The method according to claim 30, wherein aligning the multiple second optical couplers comprises positioning an optical isolator comprising a half-wave plate a Faraday rotator between the first and second optical couplers.

32. The method according to claim 31, wherein the coherent seed beam propagates through the input waveguide with a first linear polarization, while the amplified beams received through the second optical couplers have a second linear polarization, orthogonal to the first linear polarization, and wherein the splitters comprise polarization splitters.

33. The method according to claim 32, wherein both the coherent seed beam propagating through the input waveguide and the amplified beams received through the second optical couplers have a first linear polarization, and wherein the splitters comprise polarization splitters and rotators, which rotate the seed beam from the first linear polarization to a second linear polarization, orthogonal to the first linear polarization.

34. The method according to claim 30, wherein the splitters comprise directional couplers, having a first coupling ratio for conveying the seed beam from the respective taps to the second optical couplers and a second coupling ratio, which is at least twice the first coupling ratio, for conveying the amplified beams output by the multi-pass semiconductor optical gain media from the second optical couplers to the output waveguides.
